(19) United States
(12) Patent Application Publication
(10) Pub. No.: US 2024/0242978 A1
(43) Pub. Date: Jul. 18, 2024

(54) SUBSTRATE PROCESSING APPARATUS AND SUBSTRATE PROCESSING APPARATUS MAINTENANCE METHOD

(71) Applicant: Tokyo Electron Limited, Tokyo (JP)

(72) Inventors: Shota UMEZAKI, Koshi City (JP); Shigeru MORIYAMA, Koshi City (JP); Tomotaka OMAGARI, Koshi City (JP); Keiichi YAHATA, Koshi City (JP); Shuji OIE, Koshi City (JP); Yuichi TANAKA, Koshi City (JP); Katsuhiro OOKAWA, Koshi City (JP); Manabu YAMANAKA, Koshi City (JP); Takuya ITAHASHI, Koshi City (JP)

(21) Appl. No.: 18/413,295

(22) Filed: Jan. 16, 2024

(30) Foreign Application Priority Data
Jan. 17, 2023 (JP) 2023-004942

(51) Int. Cl. H01L 21/67; F26B 5/04

(52) U.S. Cl. CPC H01L 21/67034; F26B 5/04; H01L 21/67126; H01L 21/67242

(57) ABSTRACT

A substrate processing apparatus includes a drying unit for replacing a liquid film formed on a substrate with a supercritical fluid to dry the substrate, and a control device. The drying unit includes a pressure container, a supply mechanism for supplying fluid to the pressure container, a discharge mechanism for discharging the fluid from the pressure container, a panel for separating an internal space from an external space, an electromagnetic lock, and a concentration sensor for detecting a concentration of the fluid. An unlocking condition for the control device to switch a state of the electromagnetic lock from a locked state to an unlocked state includes a condition that a detection value of the pressure sensor is less than or equal to a first threshold value and a condition that a detection value of the concentration sensor is less than or equal to a second threshold value.

### CROSS-REFERENCE TO RELATED APPLICATION

This application is based upon and claims the benefit of priority from Japanese Patent Application No. 2023-004942, filed on Jan. 17, 2023, the entire contents of which are incorporated herein by reference.

### TECHNICAL FIELD

The present disclosure relates to a substrate processing apparatus and a substrate processing apparatus maintenance method.

### BACKGROUND

A substrate processing apparatus disclosed in Patent Document 1 includes a drying unit that replaces a liquid film formed on the upper surface of a substrate W in a horizontal state with a supercritical fluid and dries the substrate. The drying unit includes a processing container and a lid that closes an opening of the processing container. A similar technique is also disclosed in Patent Document 2.

### PRIOR ART DOCUMENT

### Patent Document

Patent Document 1: Japanese Laid-Open Patent Publication No. 2021-125472
Patent Document 2: Japanese Laid-Open Patent Publication No. 2013-033962

### SUMMARY

According to one embodiment of the present disclosure, a substrate processing apparatus includes a drying unit configured to replace a liquid film formed on an upper surface of a substrate in a horizontal state with a supercritical fluid and dry the substrate, and a control device. The drying unit includes a pressure container including a drying chamber provided therein to dry the substrate, a supply mechanism configured to supply a fluid to the pressure container, a discharge mechanism configured to discharge the fluid from the pressure container, a panel configured to separate an internal space in which the pressure container, the supply mechanism and the discharge mechanism are arranged, from an external space, an electromagnetic lock configured to be switched between a locked state in which the panel is fixed at a position that restricts access from the external space to the internal space and an unlocked state in which the panel is allowed to move; a pressure sensor configured to detect a pressure of the fluid, and a concentration sensor configured to detect a concentration of the fluid. An unlocking condition for the control device to switch a state of the electromagnetic lock from the locked state to the unlocked state includes a condition that a detection value of the pressure sensor is less than or equal to a first threshold value and a condition that a detection value of the concentration sensor is less than or equal to a second threshold value.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view of a substrate processing apparatus according to one embodiment.

FIG. 2 is a flowchart illustrating a substrate processing method according to one embodiment.

FIG. 3A is a sectional view showing an example of a standby position of a lid, FIG. 3B is a sectional view showing an example of an open position of the lid, and FIG. 3C is a sectional view showing an example of a closed position of the lid.

FIG. 4A is a side view showing an example of a state of a drying unit when a substrate is processed, and FIG. 4B is a sectional view taken along line B-B in FIG. 4A.

FIG. 5A is a side view showing an example of a state of the drying unit when the substrate is loaded and unloaded, and FIG. 5B is a sectional view taken along line B-B in FIG. 5A.

FIG. 6 is a flowchart showing an example of an operation of the drying unit.

FIG. 7A is a sectional view showing an example of a state in which a rotary shaft is fitted into a bearing holder, and FIG. 7B is a sectional view showing an example of a state in which the rotary shaft is separated from the bearing holder.

FIG. 8 is a diagram showing a support member shown in FIG. 7A as viewed from an X-axis positive direction.

FIG. 9A is a plan view showing an example of a state in which a bearing holder is connected to a slider, and FIG. 9B is a plan view showing an example of a state in which the bearing holder is separated from the slider.

FIG. 10 is a cross-sectional view taken along line X-X in FIG. 9A.

FIG. 11A is a sectional view showing an example of an operation of a guide arm, and is a sectional view showing an example of a state in which a lid is located at a closed position, and FIG. 11B is a sectional view showing an example of the operation of the guide arm subsequent to FIG. 11A.

FIG. 12A is a sectional view showing an example of the operation of the guide arm subsequent to FIG. 11B and FIG. 12B is a sectional view showing an example of the operation of the guide arm subsequent to FIG. 12A.

FIG. 13 is a flowchart illustrating a substrate processing apparatus maintenance method according to one embodiment.

FIG. 14 is a flowchart showing a modification of the maintenance method shown in FIG. 13.

FIG. 15 is a diagram illustrating an example of a fluid flow path of a drying unit.

### DETAILED DESCRIPTION

Embodiments of the present disclosure will be described below with reference to the drawings. In each drawing, the same or corresponding configurations are designated by like reference numerals, and the description thereof may be omitted. In this specification, the X-axis direction, Y-axis direction, and Z-axis direction are directions perpendicular to each other. The X-axis direction and the Y-axis direction are horizontal directions, and the Z-axis direction is a vertical direction. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

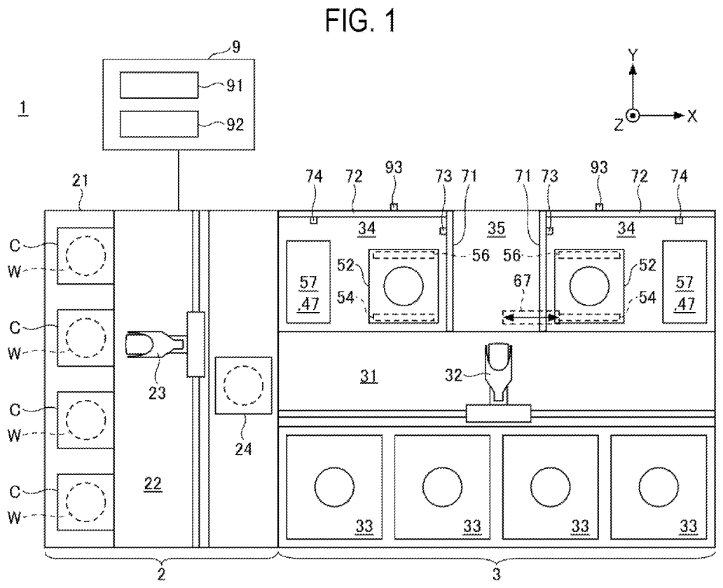

Referring first to FIG. 1, a substrate processing apparatus 1 according to an embodiment will be described. As shown in FIG. 1, the substrate processing apparatus 1 includes a loading/unloading station 2, a processing station 3, and a control device 9. The loading/unloading station 2 and the processing station 3 are arranged in the named order from an X-axis negative direction side to an X-axis positive direction side.

The loading/unloading station 2 includes a stage 21, a second transfer region 22, a second transfer device 23, and a transition unit 24. The stage 21 places a plurality of carriers C thereon. Each of the plurality of carriers C accommodates a plurality of substrates W in a horizontal state at intervals in the vertical direction.

The substrate W includes a semiconductor substrate such as a silicon wafer or a compound semiconductor wafer, or a glass substrate. The substrate W may further include a device such as an electronic circuit formed on the surface of a semiconductor substrate or a glass substrate. The substrate W may have an unevenness pattern on its surface.

The second transfer region 22 is provided adjacent to the stage 21. The second transfer device 23 transfers the substrate W in the second transfer region 22. The second transfer device 23 includes a second transfer arm that holds the substrate W. The second transfer arm may move in the horizontal direction (both the X-axis direction and the Y-axis direction) and in the vertical direction, and may rotate around the vertical axis. The number of second transfer arms may be one or more.

The transition unit 24 is provided on the opposite side of the stage 21 with respect to the second transfer region 22, and is provided adjacent to the second transfer region 22. The transition unit 24 temporarily accommodates the substrate W. A plurality of transition units 24 may be stacked one above another in the vertical direction. The arrangement and number of transition units 24 are not particularly limited.

The processing station 3 includes a first transfer region 31, a first transfer device 32, a liquid film forming unit 33, a drying unit 34, and a maintenance region 35. The first transfer region 31 is provided on the opposite side of the second transfer region 22 with respect to the transition unit 24 and is provided adjacent to the transition unit 24.

The first transfer device 32 transfers the substrate W in the first transfer region 31. The first transfer device 32 includes a first transfer arm that holds the substrate W. The first transfer arm may move in the horizontal direction (both the X-axis direction and the Y-axis direction) and in the vertical direction, and may rotate around the vertical axis. The number of first transfer arms may be one or more.

The liquid film forming unit 33 supplies a liquid to the upper surface of the substrate W in a horizontal state. The liquid film forming unit 33 includes, for example, a spin chuck that holds the substrate W horizontally and a nozzle that discharges a liquid onto the upper surface of the substrate W. The nozzle supplies the liquid to the center of the upper surface of the rotating substrate W. The liquid wets and spreads from the center of the upper surface of the substrate W toward the peripheral edge thereof by a centrifugal force. As the liquid, for example, a chemical liquid, a rinsing liquid, and a drying liquid are supplied in the named order. A plurality of types of chemical liquids may be supplied, and a rinsing liquid may be supplied between the supply of one chemical liquid and the supply of another chemical liquid.

For example, the liquid film forming unit 33 forms a liquid film of a chemical liquid on the upper surface of the substrate W in a horizontal state, then replaces the liquid film of the chemical liquid with a liquid film of a rinsing liquid, and then replaces the liquid film of the rinsing liquid with a liquid film of a drying liquid. The chemical liquid is, for example, a SCi (aqueous solution of ammonia and hydrogen peroxide) or a DHF (diluted hydrofluoric acid). The rinsing liquid is, for example, DIW (deionized water). The drying liquid is, for example, an organic solvent such as IPA (isopropyl alcohol).

The liquid film forming unit 33 is provided adjacent to the first transfer region 31. As shown in FIG. 1, a plurality of liquid film forming units 33 may be provided along the X-axis direction on one side (e.g., the Y-axis negative direction side) of the first transfer region 31. Further, a plurality of liquid film forming units 33 may be stacked one above another in the vertical direction.

The drying unit 34 replaces the liquid film formed on the upper surface of the substrate W in a horizontal state with a supercritical fluid, and dries the substrate W. The supercritical fluid is a fluid kept under a temperature higher than a critical temperature and a pressure higher than a critical pressure, and is a fluid kept in a state in which it is impossible to distinguish between a liquid and a gas. By replacing the liquid film such as a drying liquid with the supercritical fluid, it is possible to suppress the collapse of an unevenness pattern on the substrate W due to surface tension.

The drying unit 34 includes a pressure container 52 provided with a drying chamber formed therein to dry the substrate W, lids 54 and 56 that close the openings of the pressure container 52, a supply mechanism 57 that supplies a fluid to the inside of the pressure container 52, and a discharge mechanism 47 that discharges a fluid from the inside of the pressure container 52. The supply mechanism 57 supplies, for example, CO₂ as a fluid into the pressure container 52. Although the supply mechanism 57 and the discharge mechanism 47 are provided integrally in FIG. 1, they may be provided separately.

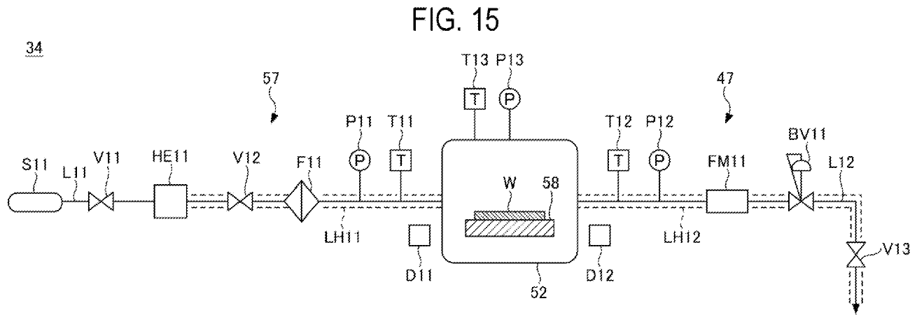

As shown in FIG. 15, the supply mechanism 57 includes a supply passage L11. A fluid source S11, an on-off valve V11, a heating mechanism HE11, an on-off valve V12, a filter F11, a pressure sensor P11, and a temperature sensor T11 are provided in the supply passage L11 in the named order from the upstream side to the downstream side. Further, a line heater LH11 is provided in the supply passage L11 at the downstream side of the heating mechanism HE11. The supply passage L11 may further include an orifice, an on-off valve, a temperature sensor, a pressure sensor, and the like (all not shown).

The fluid source S11 includes a source of fluid. The fluid includes, for example, carbon dioxide (CO₂) and nitrogen (N₂). The on-off valves V11 and V12 are valves that open and close the supply passage L11. The on-off valves V11 and V12 open the supply passage L11 so as to flow the fluid to the downstream side, and closes the supply passage L11 so as not to flow the fluid to the downstream side. The heating mechanism HE11 heats the fluid to a set temperature and supplies the fluid heated at the set temperature to the downstream side. The filter F11 filters the fluid flowing through the supply passage L11 to remove foreign substances contained in the fluid. The pressure sensor P11 detects a pressure of the fluid flowing through the supply passage L11. The pressure sensor P11 is provided immediately before the pressure container 52, for example. The temperature sensor T11 detects a temperature of the fluid flowing through the supply passage L11. The temperature sensor T11 is provided immediately before the pressure container 52, for example. The line heater LH11 is provided downstream of the heating mechanism HE11 to suppress a decrease in the temperature of the fluid.

The discharge mechanism 47 includes a discharge passage L12. A temperature sensor T12, a pressure sensor P12, a flow meter FM11, a back-pressure valve BV11, and an on-off valve V13 are provided in the discharge passage L12 in the maned order from the upstream side to the downstream side. A line heater LH12 is provided in the discharge passage L12. An on-off valve, a temperature sensor, a pressure sensor, and the like (all not shown) are further provided in the discharge passage L12. etc.

The temperature sensor T12 detects a temperature of the fluid flowing through the discharge passage L12. The temperature sensor T12 is provided immediately after the pressure container 52, for example. The pressure sensor P12 detects a pressure of the fluid flowing through the discharge passage L12. The pressure sensor P12 is provided immediately after the pressure container 52, for example. The flow meter FM11 detects a flow rate of the fluid flowing through the discharge passage L12. The back-pressure valve BV11 maintains a primary pressure at a set pressure to maintain the pressure of the pressure container 52 at the set pressure. The set pressure of the back-pressure valve BV11 may be appropriately changed. The on-off valve V13 is a valve that opens and closes the discharge passage L12. The on-off valve V13 opens the discharge passage L12 so as to flow the fluid to the downstream side, and closes the discharge passage L12 so as not to flow the fluid to the downstream side. The line heater LH12 heats the discharge passage L12 to suppress a decrease in the temperature of the fluid.

The drying unit 34 includes a pressure sensor P13 and a temperature sensor T13. The pressure sensor P13 detects a pressure of the fluid inside the pressure container 52. The temperature sensor T13 detects a temperature of the fluid inside the pressure container 52.

Further, the drying unit 34 includes concentration sensors D11 and D12. The concentration sensors D11 and D12 are examples of leakage sensors that detect leakage of fluid from the inside of the pressure container 52 to the outside thereof. The concentration sensors D11 and D12 detect a concentration of the fluid (for example, CO₂). Further, the pressure sensor P13 may be used as the leakage sensor.

As shown in FIG. 1, the drying unit 34 is provided adjacent to the first transfer region 31. As shown in FIG. 1, a plurality of drying units 34 may be provided along the X-axis direction on the opposite side of the first transfer region 31 (e.g., on the Y-axis positive direction side) with respect to the liquid film forming units 33. Further, a plurality of drying units 34 may be stacked one above another in the vertical direction.

The maintenance region 35 is a region into which an operator enters when performing maintenance on the drying unit 34. The maintenance region 35 is provided on the same side as the drying unit 34 (e.g., on the Y-axis positive direction side) of the first transfer region 31. The maintenance region 35 is provided between two drying units 34 adjacent to each other in the X-axis direction.

The control device 9 is, for example, a computer, and includes a calculator 91 such as a CPU (Central Processing Unit) or the like, and a storage 92 such as a non-transient computer readable storage device such as a memory or the like. The storage 92 stores a program that control various processes executed in the substrate processing apparatus 1. The control device 9 controls the operation of the substrate processing apparatus 1 by causing the calculator 91 to execute the program stored in the storage 92. Unit controllers may be provided for controlling the operation of the respective units constituting the substrate processing apparatus 1, and a system controller may be provided for controlling the unit controllers in an integrated manner. The control device 9 may be configured by the unit controllers and the system controller.

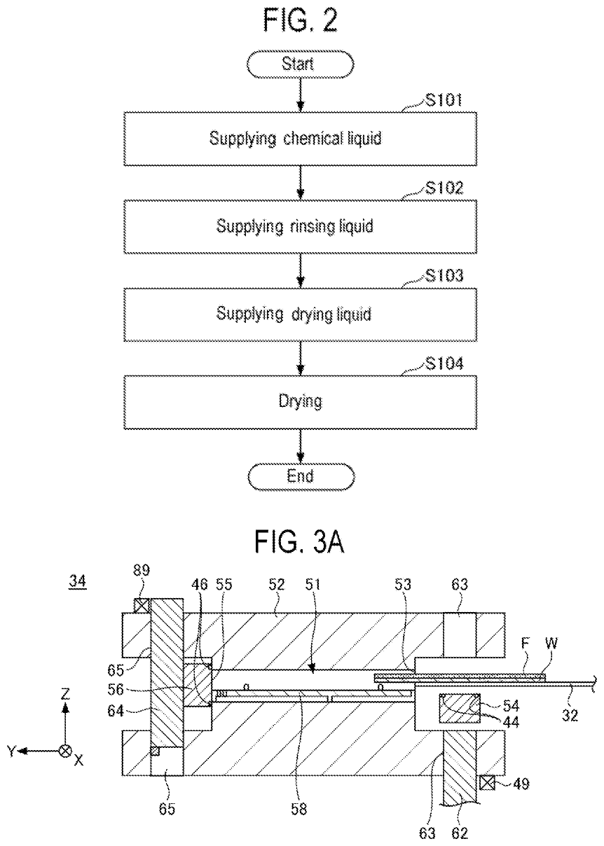

Next, a substrate processing method according to an embodiment will be described with reference to FIG. 2. Steps S101 to S104 shown in FIG. 2 are performed under the control of the control device 9. First, the second transfer device 23 takes out the substrate W from the carrier C and transfers the taken-out substrate W to the transition unit 24. Subsequently, the first transfer device 32 takes out the substrate W from the transition unit 24 and transfers the taken-out substrate W to the liquid film forming unit 33.

Subsequently, the liquid film forming unit 33 supplies a chemical liquid onto the upper surface of the substrate W in a horizontal state (step S101). The chemical liquid is supplied to the center of the upper surface of the rotating substrate W. The chemical liquid spreads over the entire upper surface in the radial direction by a centrifugal force to form a liquid film.

Subsequently, the liquid film forming unit 33 supplies a rinsing liquid to the upper surface of the substrate W in a horizontal state (step S102). The rinsing liquid is supplied to the center of the upper surface of the rotating substrate W. The rinsing liquid spreads over the entire upper surface in the radial direction by a centrifugal force to form a liquid film. The liquid film of the chemical liquid is replaced by a liquid film of the rinsing liquid.

Subsequently, the liquid film forming unit 33 supplies a drying liquid to the upper surface of the substrate W in a horizontal state (step S103). The drying liquid is supplied to the center of the upper surface of the rotating substrate W. The drying liquid spreads over the entire upper surface in the radial direction by a centrifugal force to form a liquid film. The liquid film of the rinsing liquid is replaced by a liquid film of the drying liquid.

Subsequently, the first transfer device 32 takes out the substrate W from the liquid film forming unit 33 and transfers the taken-out substrate W to the drying unit 34.

Subsequently, the drying unit 34 replaces the liquid film formed on the upper surface of the substrate W in a horizontal state with a supercritical fluid to dry the substrate W (step S104). By replacing the liquid film such as the drying liquid or the like with the supercritical fluid, it is possible to suppress the appearance of an interface between a liquid and a gas in the unevenness pattern of the substrate W. As a result, it is possible to suppress the generation of surface tension and to suppress the collapse of the unevenness pattern.

Finally, the first transfer device 32 takes out the substrate W from the drying unit 34 and transfers the taken-out substrate W to the transition unit 24. Subsequently, the second transfer device 23 takes out the substrate W from the transition unit 24 and stores the taken-out substrate W in the carrier C.

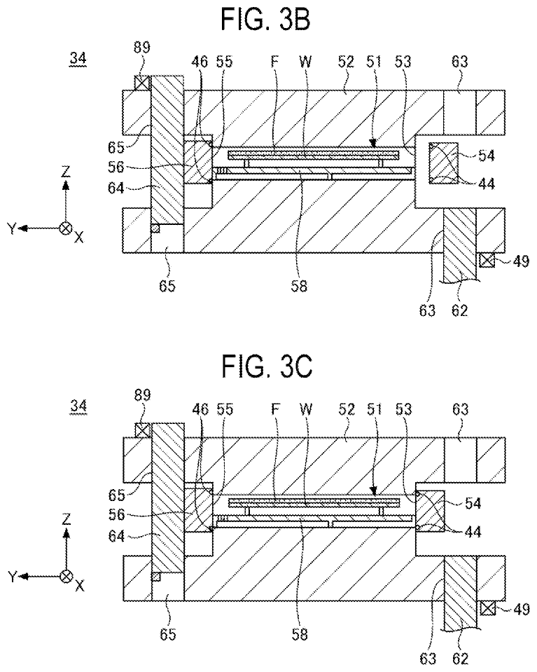

Next, an example of the drying unit 34 will be described with reference to FIGS. 3A to 5B. In the description of the drying unit 34, a direction in which the substrate W is loaded from the first transfer region 31 into the drying unit 34 (e.g., the Y-axis positive direction) will be referred to as a front side, and a direction in which the substrate W is unloaded from the drying unit 34 to the first transfer region 31 (e.g., the Y-axis negative direction) will be referred to as a rear side.

The drying unit 34 includes a pressure container 52 provided with a drying chamber 51 formed therein to dry the substrate W, a lid 54 that closes an opening 53 of the pressure container 52, a lid 56 that closes an opening 55 of the pressure container 52, and a support body 58 that horizontally supports the substrate W inside the pressure container 52. The opening 53 is a loading/unloading port through which the substrate W passes, and is formed on the rear surface of the pressure container 52. On the other hand, the opening 55 is formed on the front surface of the pressure container 52. The pressure container 52 is provided so that the opening 53 faces the first transfer region 31. The substrate W is loaded into the drying chamber 51 through the opening 53, dried in the drying chamber 51, and then unloaded from the drying chamber 51 through the opening 53.

The lid 54 is moved forward and backward between a closed position (see FIG. 3C) and an open position (see FIG. 3B). The closed position is a position at which the lid 54 closes the opening 53. The open position is behind the closed position and is a position at which the lid 54 opens the opening 53. Further, the lid 54 is rotated between the open position and the standby position (see FIG. 3A). The standby position is a position away from the loading/unloading path of the substrate W. When loading and unloading the substrate W, the lid 54 waits at the standby position. As a result, the first transfer device 32 may easily enter the drying chamber 51.

In Patent Document 1, the support body 58 is not fixed to the pressure container 52 but is fixed to the lid 54. The support body 58 moves forward and backward together with the lid 54. Then, the first transfer device 32 and the support body 58 deliver the substrate W outside the pressure container 52. Therefore, an area for delivering the substrate W is provided outside the pressure container 52.

According to this embodiment, the support body 58 is fixed to the pressure container 52 and does not move forward or backward together with the lid 54. Inside the pressure container 52, the first transfer device 32 and the support body 58 deliver the substrate W. Therefore, there is no need to provide an area for delivering the substrate W outside the pressure container 52, which makes it possible to downsize the drying unit 34.

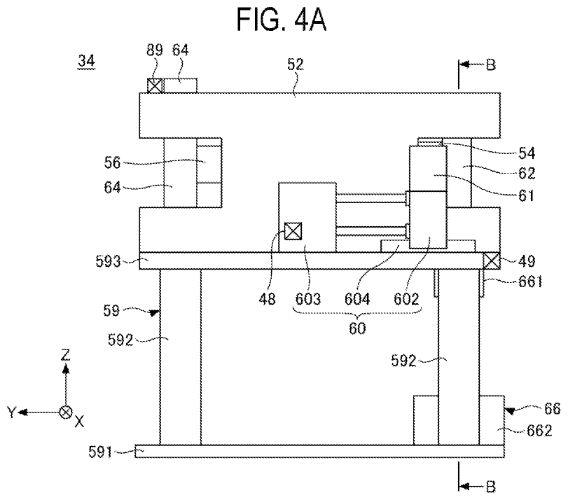

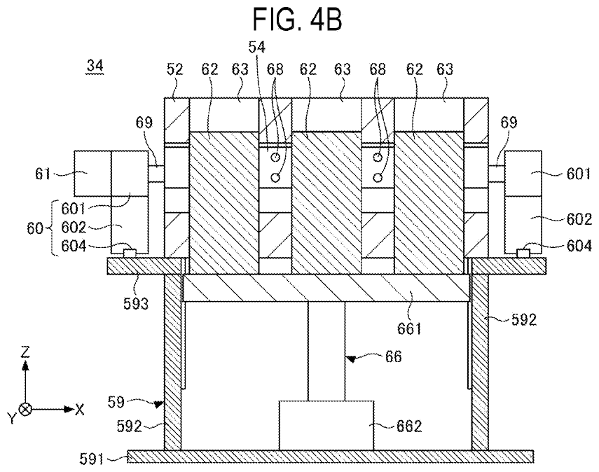

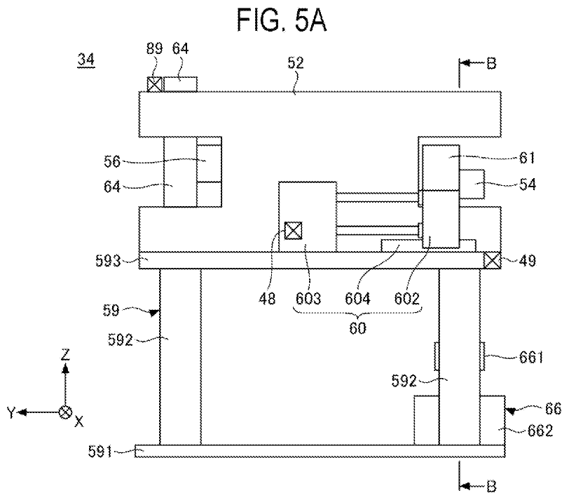

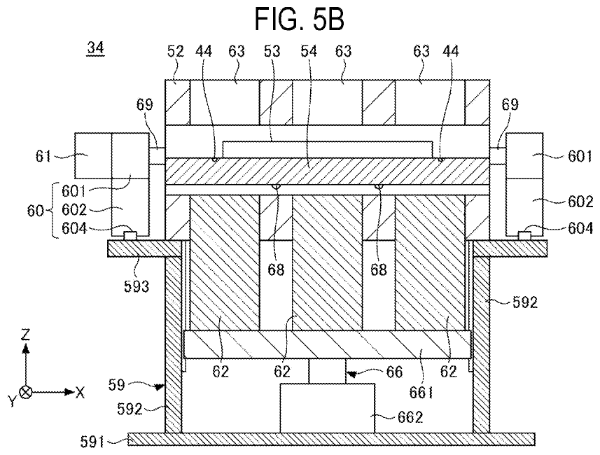

As shown in FIGS. 4A and 4B and FIGS. 5A and 5B, the drying unit 34 includes a support frame 59 that supports the pressure container 52. The support frame 59 includes, for example, a horizontal base plate 591, a plurality of columns 592 projecting upward from the base plate 591, and a horizontal plate 593 fixed to the upper surface of the plurality of columns 592. The horizontal plate 593 is assembled in a rectangular frame shape, for example. The pressure container 52 is fixed on the horizontal plate 593.

The drying unit 34 includes a linear motion mechanism 60 and a rotation mechanism 61. The linear motion mechanism 60 and the rotation mechanism 61 are one example of a first driver that moves the lid 54. The linear motion mechanism 60 moves the lid 54 forward and backward between the closed position and the open position. The rotation mechanism 61 rotates the lid 54 between the open position and the standby position. The drying unit 34 includes a pair of rotary shafts 69 that protrude from the lid 54 in the X-axis positive direction and the X-axis negative direction. The rotation mechanism 61 rotates the lid 54, for example, by rotating the rotary shaft 69.

The linear motion mechanism 60 includes, for example, bearing holders 601 that hold bearings of the rotary shaft 69, and a slider 602 to which the bearing holders 601 are removably connected. The bearing holders 601 are provided on both sides in the X-axis direction with the lid 54 interposed therebetween. The slider 602 is moved along a guide 604 laid on the horizontal plate 593. The slider 602 and the guide 604 are provided on both sides of the pressure container 52 in the X-axis direction.

The linear motion mechanism 60 includes a linear motion actuator 603 that moves the slider 602 forward and backward in the Y-axis direction. The linear actuator 603 is, for example, a pneumatic cylinder, and presses the lid 54 against the pressure container 52 using the pressure of a compressed air. This may prevent the lid 54 from interfering with the lifting of a lock key 62, which will be described later. The linear actuator 603 may include a rotation motor and a ball screw that converts the rotational motion of the rotation motor into linear motion of the lid 54.

The linear actuator 603 is arranged, for example, on one side of the pressure container 52 and arranged closer to the maintenance region 35 than the pressure container 52. Maintenance of the linear actuator 603 is easy. The linear actuator 603 moves the lid 54 forward and backward by pushing and pulling one of the pair of sliders 602 that is closer to the maintenance region 35. The linear actuator 603 is fixed to the horizontal plate 593.

The rotation mechanism 61 includes, for example, a rotary actuator, and generates a rotational force using an air pressure. The rotation mechanism 61 may include a rotation motor. The rotation mechanism 61 is arranged, for example, on one side of the pressure container 52 and arranged closer to the maintenance region 35 than the pressure container 52. Maintenance of the rotation mechanism 61 is easy. The rotation mechanism 61 is fixed to one of the pair of bearing holders 601 that is closer to the maintenance region 35, and is moved forward and backward together with the bearing holder 601.

As shown in FIGS. 3A and 3B, the drying unit 34 includes a lock key 62 that presses the lid 54 from the rear side. The pressure container 52 has a pair of upper and lower convex portions on its rear surface with the opening 53 interposed therebetween. A pair of upper and lower fitting holes 63 are formed to vertically penetrate the pair of upper and lower convex portions. The lock key 62 is fitted into the pair of upper and lower fitting holes 63 of the pressure container 52 to press the lid 54. Even if the pressure in the drying chamber 51 is increased, it is possible to suppress fluid leakage.

The drying unit 34 also includes a lock key 64 that presses the lid 56 from the front side. The pressure container 52 has a pair of upper and lower convex portions on its front surface with the opening 55 interposed therebetween. A pair of upper and lower fitting holes 65 are formed to vertically penetrate the pair of upper and lower convex portions. The lock key 64 is fitted into the pair of upper and lower fitting holes 65 of the pressure container 52 to press the lid 56. Even if the pressure in the drying chamber 51 is increased, it is possible to suppress fluid leakage.

The drying unit 34 includes an elevating mechanism 66 that raises and lowers the lock key 62 between a locked position (see FIG. 4B) and an unlocked position (see FIG. 5B). The elevating mechanism 66 is one example of a second driver that moves the lock key 62. The locked position is a position at which the lock key 62 limits the retreat of the lid 54 and a position at which the lock key 62 is fitted into both of the pair of upper and lower fitting holes 63. The unlocked position is a position at which the lock key 62 allows the lid 54 to retreat and a position at which the lock key 62 is pulled out downward from the upper fitting hole 63. The unlocked position is set below the loading/unloading path of the substrate W in order to prevent interference between the lock key 62 and the substrate W.

The elevating mechanism 66 includes, for example, an elevating table 661 on which a plurality of lock keys 62 are placed, and a linear actuator 662 that raises and lowers the elevating table 661. The linear actuator 662 is, for example, a pneumatic cylinder, and raises and lowers the plurality of lock keys 62 by raising and lowering the elevating table 661. The linear actuator 662 may include a rotation motor and a ball screw that converts the rotational motion of the rotation motor into linear motion of the elevating table 661.

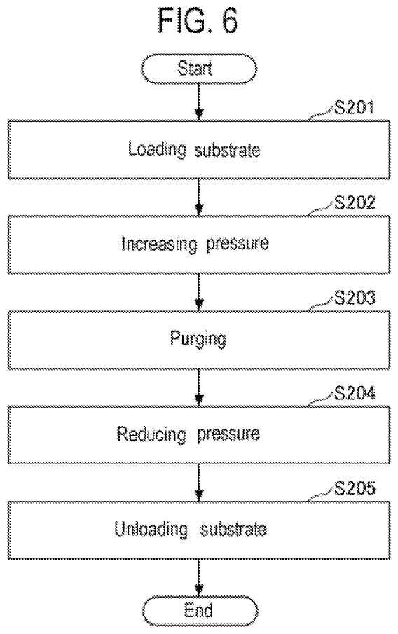

Next, an example of the operation of the drying unit 34 will be described with reference to FIG. 6. Steps S201 to S205 shown in FIG. 6 are performed under the control of the control device 9. First, the first transfer device 32 horizontally holds the substrate W on which a drying liquid film F is formed, and loads the substrate W into the drying chamber 51 formed inside the pressure container 52 (step S201). Subsequently, the support body 58 fixed to the drying chamber 51 receives the substrate W from the first transfer device 32 and horizontally supports the received substrate W. Subsequently, the first transfer device 32 is withdrawn from the opening 53 of the pressure container 52.

Subsequently, the rotation mechanism 61 rotates the lid 54 from the standby position to the open position. Subsequently, the linear motion mechanism 60 advances the lid 54 from the open position to the closed position. As a result, the lid 54 closes the opening 53 of the pressure container 52. Subsequently, the elevating mechanism 66 raises the lock key 62 from the unlocked position to the locked position. The lock key 62 presses the lid 54 from the rear side and restrains the retreat of the lid 54.

Subsequently, the supply mechanism 57 supplies a fluid such as CO₂ or the like to the drying chamber 51 to increase the pressure in the drying chamber 51 (step S202). While the pressure in the drying chamber 51 is being increased, the fluid is not discharged from the drying chamber 51 but stays in the drying chamber 51. The pressure in the drying chamber 51 is increased to a preset pressure equal to or higher than the critical pressure.

Subsequently, the supply mechanism 57 supplies the fluid to the drying chamber 51. A discharge mechanism 47 discharges the fluid from the drying chamber 51. While maintaining the pressure in the drying chamber 51 at the preset pressure, the drying liquid dissolved in the fluid of a supercritical state is purged (step S203). As a result, the liquid film F is replaced with a supercritical fluid.

Subsequently, the supply mechanism 57 stops supplying the fluid to the drying chamber 51, and the discharge mechanism 47 discharges the fluid from the drying chamber 51 to reduce the pressure in the drying chamber 51 (step S204). The discharge mechanism 47 may include a vacuum pump, an ejector, and the like to shorten the pressure reduction time. The pressure in the drying chamber 51 is reduced approximately to the atmospheric pressure.

Subsequently, the elevating mechanism 66 lowers the lock key 62 from the locked position to the unlocked position. Subsequently, the linear motion mechanism 60 retreats the lid 54 from the closed position to the open position. Subsequently, the rotation mechanism 61 rotates the lid 54 from the open position to the standby position. Finally, the first transfer device 32 enters the drying chamber 51 formed inside the pressure container 52, receives the substrate W from the support body 58, and unloads the received substrate W (step S205).

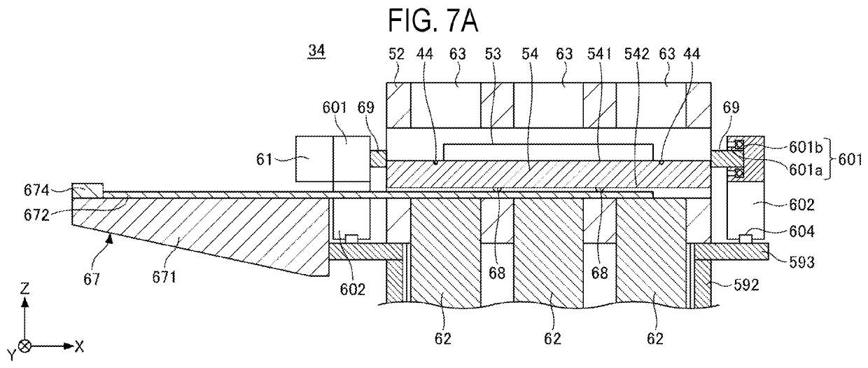

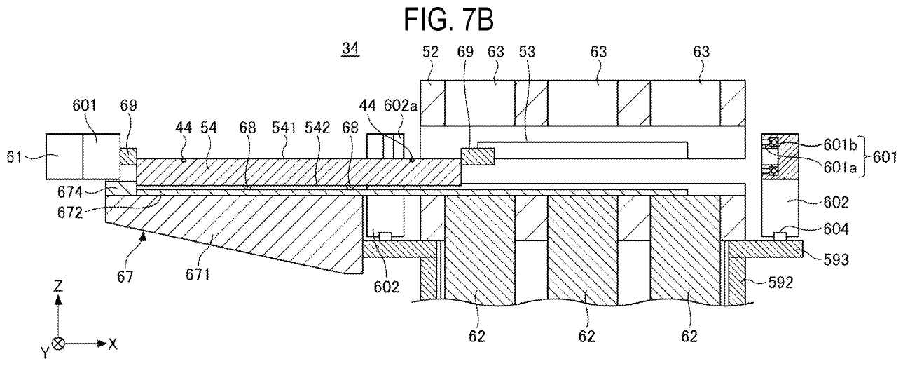

Next, an example of the maintenance of the drying unit 34 will be described with reference to FIG. 1, FIGS. 7A and 7B, and FIGS. 8 to 10. As shown in FIG. 1, the maintenance region 35 filled with an air is provided between two drying units 34 adjacent to each other in the X-axis direction. The operator enters the maintenance region 35 and performs maintenance on the drying unit 34. The maintenance of the drying unit 34 includes, for example, cleaning or replacing a sealing member 44 attached to the lid 54. The operator does not need to enter the first transfer region 31 and does not need to wear an oxygen mask or the like.

Further, since the operator does not enter the first transfer region 31, the control device 9 does not have to completely stop the operation of the first transfer device 32. The control device 9 only needs to prohibit the transfer of the substrate W to the drying unit 34 to be maintained, and allows the transfer of the substrate W to the remaining drying unit 34. The substrate W may be dried in another drying unit 34 during the maintenance of one drying unit 34. This makes it possible to suppress a decrease in the operating rate of the substrate processing apparatus 1.

The control device 9 provides a notification for each drying unit 34 to prompt maintenance of the drying unit 34. The notification includes a screen display, an audio output, and the like. The timing of notification is determined based on the elapsed time since the last maintenance, the number of substrates W processed, or the like. After the notification, when the operator performs a preset input operation, the control device 9 implements a maintenance mode in which the transfer of the substrate W to the drying unit 34 is prohibited. The control device 9 selects whether to implement the maintenance mode for each drying unit 34.

As shown in FIGS. 7A and 7B, the substrate processing apparatus 1 includes a support member 67. The support member 67 supports the lid 54 so as to be movable in both a first direction (e.g., the X-axis negative direction) parallel to the opening 53 and a second direction (e.g., the X-axis positive direction) opposite to the first direction. By allowing the support member 67 to support the lid 54, which is a heavy object, it is possible to reduce the burden on the operator. Therefore, the maintainability may be improved. Although the support member 67 movably supports the lid 54 in this embodiment, it may also movably support another lid 56.

The lid 54 is moved in a direction parallel to the opening 53 in a state in which the support member 67 supports the lid 54. Even if a panel facing the opening 53 exists near the opening 53, the lid 54 may be pulled out from the gap between the panel and the pressure container 52 by moving the lid 54 parallel to the panel. This makes it possible to perform the maintenance of the lid 54. The moving direction of the lid 54 may be a direction parallel to the opening 53 and is not limited to the horizontal direction. The moving direction of the lid 54 may be a vertical direction, or a direction inclined with respect to the horizontal direction and the vertical direction.

The opening 53 is a loading/unloading port through which the substrate W passes. In a state in which the support member 67 supports the lid 54, the lid 54 is moved in a direction perpendicular to the loading direction (e.g., the Y-axis positive direction) and the unloading direction (e.g., the Y-axis negative direction) of the substrate W. As shown in FIG. 1, the support member 67 is provided so as not to protrude from the drying unit 34 in the direction (Y-axis negative direction) in which the substrate W is unloaded. In other words, the support member 67 is provided so as not to protrude from the drying unit 34 into the first transfer region 31. As a result, it is not necessary to completely stop the operation of the first transfer device 32, and it is possible to suppress a decrease in the operating rate of the substrate processing apparatus 1.

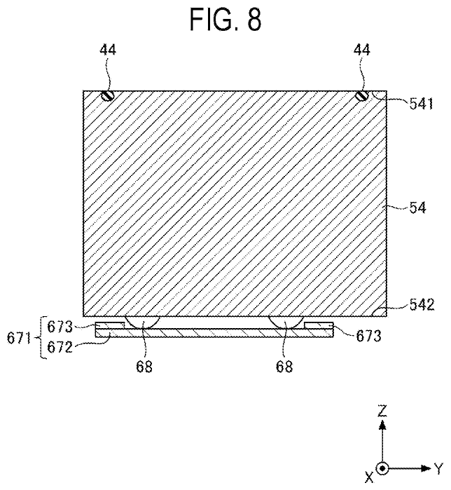

As shown in FIGS. 7A and 7B, the support member 67 includes, for example, a linear motion guide 671 that guides the lid 54. The linear motion guide 671 includes, for example, a horizontal plate 672 on which the lid 54 is placed, a pair of guards 673 (see FIG. 8) that guide the lid 54 in the first direction and the second direction, and a stopper 674 that limits the movement range of the lid 54 in the first direction. The pair of guards 673 and the stopper 674 are provided on the upper surface of the horizontal plate 672.

The lid 54 includes rolling elements 68. The rolling elements 68 are balls or rollers (balls in this embodiment). By rolling while contacting the support member 67, the rolling elements 68 reduce the friction between the lid 54 and the support member 67, thereby making it possible to move the lid 54 with a small force. Although the rolling elements 68 are provided on the lid 54 in this embodiment, they may be provided on the support member 67.

The lid 54 has a first surface 541 on which a sealing member 44 is provided, and a second surface 542 opposite to the first surface 541 (see FIGS. 7A and 7B, and FIG. 8). The sealing member 44 is provided in a ring shape to surround the opening 53 and seal the drying chamber 51. The rolling elements 68 are provided on the second surface 542. The lid 54 rotates about the rotary shaft 69.

When the lid 54 is located at a first rotation position (closed position) as shown in FIG. 4B, the rolling elements 68 are arranged toward the rear side and are arranged at the positions where they do not interfere with the lock key 62, for example, between two lock keys 62 spaced apart in the X-axis direction. On the other hand, when the lid 54 is located at a second rotation position (standby position) as shown in FIG. 5B, the rolling elements 68 are arranged to face downward.

As shown in FIG. 7A, the operator inserts the horizontal plate 672 under the lid 54 in a state in which the lock key 62 is stopped at the unlocked position and the lid 54 is stopped at the second rotation position (standby position). Thereafter, the operator pulls out the lid 54 in the first direction (leftward in FIGS. 7A and 7B) from the standby position (see FIG. 7A) to the maintenance position (FIG. 7B).

As a result, the rotary shaft 69 protruding from the lid 54 in the second direction (rightward in FIGS. 7A and 7B) is separated from the bearing holder 601 on the right side in FIGS. 7A and 7B. The bearing holder 601 on the right side in FIGS. 7A and 7B includes a hollow shaft 601a into which the rotary shaft 69 is separably fitted, and a bearing 601b that rotatably supports the hollow shaft 601a. The rotary shaft 69 may be provided with an O-ring (not shown). The O-ring suppresses slippage between the rotary shaft 69 and the hollow shaft 601a, and the hollow shaft 601a rotates together with the rotary shaft 69.

The bearing holder 601 on the left side in FIGS. 7A and 7B does not have a hollow shaft 601a. The rotary shaft 69 protruding from the lid 54 in the first direction (leftward in FIGS. 7A and 7B) is fixed to the inner ring of the bearing of the bearing holder 601 on the left side in FIGS. 7A and 7B, and is not separated from the bearing holder 601 on the left side in FIGS. 7A and 7B.

As shown in FIGS. 7A and 7B, the operator may move not only the lid 54 but also the left bearing holder 601 in the first direction. The connection between the left bearing holder 601 and the slider 602 is released in advance. The rotation mechanism 61 is fixed to the left bearing holder 601, and the rotation mechanism 61 is also moved in the first direction. Therefore, the pipe for transmitting an air pressure (or the wiring for feeding electric power) is removed from the rotation mechanism 61 in advance.

The operator cleans or replaces the sealing member 44 attached to the lid 54 while the lid 54 is stopped at the maintenance position by the stopper 674. At this time, since the first surface 541 on which the sealing member 44 is provided faces upward, the sealing member 44 may be easily cleaned or replaced.

Thereafter, the operator pushes the lid 54 back from the maintenance position to the standby position in the second direction (rightward in FIGS. 7A and 7B). As a result, the rotary shaft 69 protruding from the lid 54 in the second direction is fitted into the hollow shaft 601a. The centering of the rotary shaft 69 is completed by inserting the rotary shaft 69 into the hole of the hollow shaft 601a. The rotary shaft 69 or the hole of the hollow shaft 601a may have a taper shape tapering toward the second direction.

Thereafter, the operator removes the support member 67 from the pressure container 52. As a result, a space is formed below the lid 54, the lid 54 becomes rotatable about the rotary shaft 69, and the lid 54 becomes rotatable from the standby position (second rotation position) to the open position (first rotation position). The support member 67 is removably connected to the pressure container 52.

In the absence of the rotation mechanism 61, the support member 67 may be permanently connected to the pressure container 52. In that case, the support member 67 may be provided as a part of the pressure container 52. Alternatively, the support member 67 may be provided as a part (e.g., the upper portion) of the lock key 62.

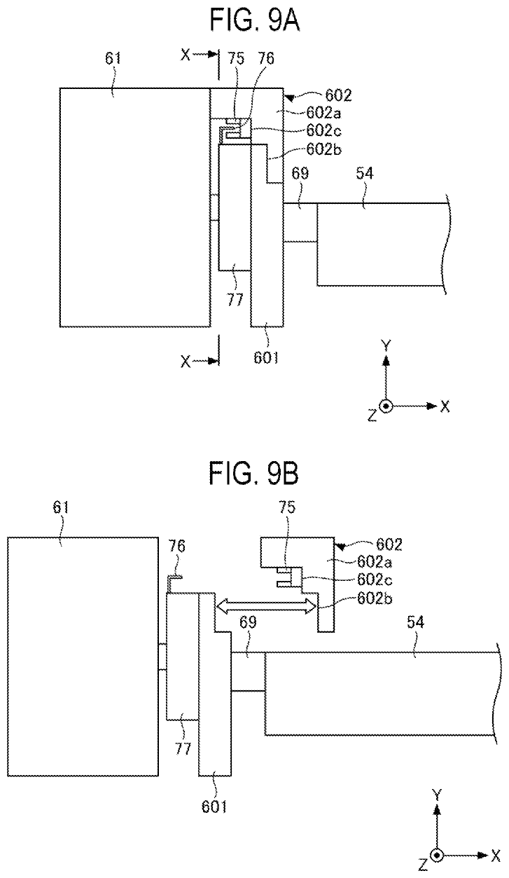

As shown in FIGS. 9A and 9B, the drying unit 34 may include a position sensor 75 configured to detect that the lid 54 is located at a desired position (e.g., the standby position). The position sensor 75 is, for example, a photoelectric sensor. The photoelectric sensor includes, for example, a light emitting part and a light receiving part that receives the light emitted from the light emitting part. When a detected object 76 is inserted between the light emitting part and the light receiving part, the intensity of the light received by the light receiving part decreases. Although the position sensor 75 is the photoelectric sensor in this embodiment, it may also be a proximity sensor, a limit switch, or the like.

The position sensor 75 is provided on the slider 602, for example. The slider 602 includes a connecting plate 602a to which the bearing holder 601 is removably connected. The connecting plate 602a may have a step between a surface 602b with which the bearing holder 601 contacts and a surface 602c on which the position sensor 75 is provided.

The detected body 76 is provided, for example, on a rotary disk 77 that rotates together with the rotary shaft 69. When the lid 54 is located at the standby position (second rotation position), the position sensor 75 detects the presence of the detected body 76. The control device 9 uses the position sensor 75 to confirm that the lid 54 is located at the standby position. As a result, it may be confirmed that the lid 54 has returned from the maintenance position to the standby position.

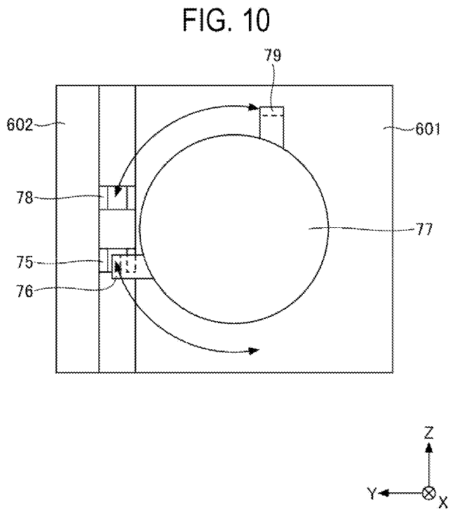

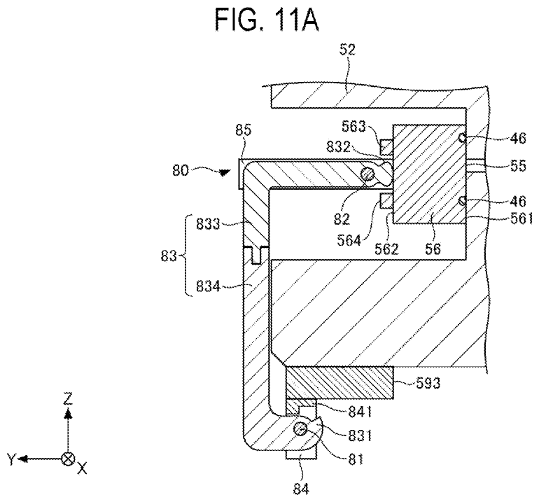

As shown in FIG. 10, the drying unit 34 may include a position sensor 78 configured to detect that the lid 54 is located at the open position (first rotation position). A detected body 79 of the position sensor 78 is provided on the rotary disk 77. When the lid 54 is located at the open position, the position sensor 78 detects the presence of the detected body 79.

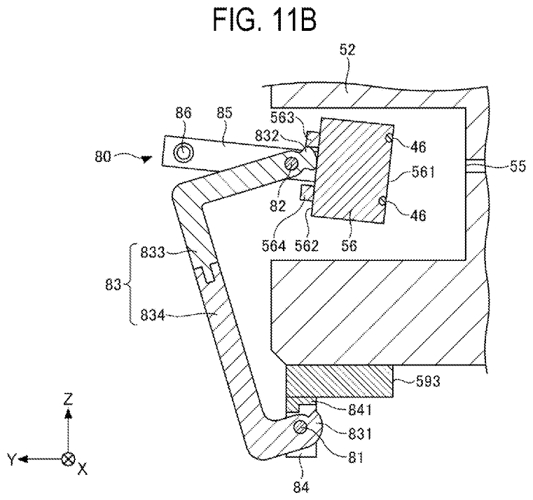

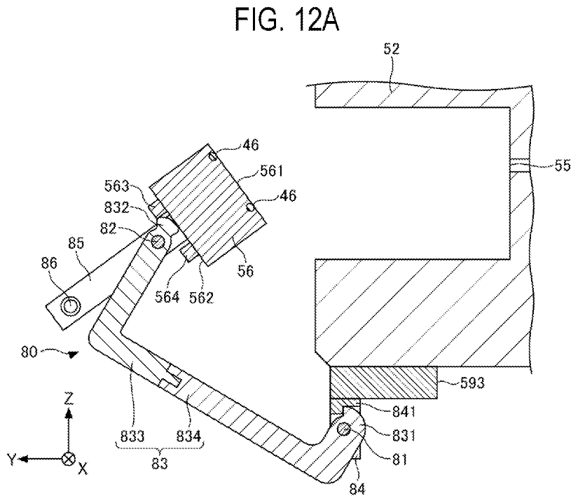

Next, an example of the support member 80 that supports the lid 56 will be described with reference to FIGS. 11A and 11B and FIGS. 12A and 12B. The support member 80 supports the lid 56 so as to be movable between a closed position (see FIG. 11A) at which the lid 56 closes the opening 55 of the pressure container 52 and a maintenance position (see FIG. 12B) at which the maintenance of the lid 56 is performed. By allowing the support member 80 to support the lid 56, which is a heavy object, it is possible to reduce the burden on the operator. Therefore, it is possible to improve the maintainability.

The support member 80 includes, for example, a guide arm 83 configured to rotate about a first rotation shaft 81 connected to the pressure container 52. By rotating the lid 56 about the first rotation shaft 81, the lid 56 may be pulled out from the pressure container 52. The lid 56 is pulled out from the pressure container 52 to the side opposite to the first transfer region 31.

The first rotation shaft 81 is attached to a support piece 84 provided on the lower surface of the horizontal plate 593 of the support frame 59, for example. The support piece 84 has a rotation stopper 841. The rotation stopper 841 limits the rotation range of the guide arm 83 by coming into contact with the protrusion 831 of the guide arm 83.

The first rotation shaft 81 extends in the X-axis direction. The first rotation shaft 81 and the guide arm 83 are provided in a pair and spaced apart in the X-axis direction. Although the guide arm 83 is used as the support member 80 that supports the lid 56 in this embodiment, it may also be used as the support member 67 that supports another lid 54.

The lid 56 has a first surface 561 on which a nozzle (not shown) and a sealing member 46 are provided, and a second surface 562 opposite to the first surface 561. The nozzle is provided inside the sealing member 46 to supply a fluid such as CO₂ or the like to the drying chamber 51. The sealing member 46 is provided in a ring shape to surround the opening 55 and seal the drying chamber 51.

The guide arm 83 supports the lid 56 so as to be rotatable about a second rotation shaft 82 parallel to the first rotation shaft 81. The orientation of the first surface 561 of the lid 56 may be changed. Rotation stoppers 563 and 564 are provided on the second surface 562 of the lid 56. The rotation stoppers 563 and 564 are provided to sandwich the protrusion 832 of the guide arm 83. The rotation stoppers 563 and 564 limit the rotation range of the lid 56 by coming into contact with the protrusion 832. This makes it possible to suppress the rotation of the lid 56 due to its own weight.

The guide arm 83 includes a first arm 833 to which the lid 56 is attached, and a second arm 834 to which the first rotation shaft 81 is attached. The first arm 833 and the second arm 834 are separably fitted to each other. By separating the first arm 833 from the second arm 834, the lid 56 may be removed together with the first arm 833. This makes it possible to further improve the maintainability.

The guide arm 83 has, for example, a U-shape. Each of the first arm 833 and the second arm 834 has, for example, an L-shape. The lid 56 is attached to one end of the first arm 833, and a convex portion is provided at the other end of the first arm 833. On the other hand, the first rotation shaft 81 is attached to one end of the second arm 834, and a concave portion is provided at the other end of the second arm 834. The convex portion of the first arm 833 and the concave portion of the second arm 834 are fitted to each other.

In this embodiment, the first arm 833 has the convex portion and the second arm 834 has the concave portion. However, the arrangement of the convex portion and the concave portion may be reversed. The first arm 833 may have a concave portion, the second arm 834 may have a convex portion, and the concave portion of the first arm 833 and the convex portion of the second arm 834 may be fitted to each other.

The operator pulls out the lock key 64 (see FIGS. 3A and 3B, and the like) upward from the pair of upper and lower fitting holes 65 in a state in which the lid 56 is stopped at the closed position as shown in FIG. 11A. Thereafter, the operator pulls out the guide arm 83 as shown in FIG. 11B. At this time, the lid 56 rotates about the second rotation shaft 82 under its own weight until the rotation stopper 563 comes into contact with the protrusion 832 as shown in FIG. 11B.

The operator further pulls out the guide arm 83 as shown in FIG. 12A. The guide arm 83 rotates about the first rotation shaft 81. When the protrusion 831 comes into contact with the rotation stopper 841, the rotation of the guide arm 83 is stopped. Thereafter, as shown in FIG. 12B, the operator rotates the lid 56 about the second rotation shaft 82 until the rotation stopper 564 comes into contact with the protrusion 832, thereby allowing the first surface 561 of the lid 56 to face upward.

The second surface 562 of the lid 56 faces downward. A rod 85 is provided to protrude from the second surface 562 of the lid 56, and an index plunger 86 is provided at the tip (the lower end in FIG. 12B) of the rod 85. The operator extends the pin of the index plunger 86 and brings the pin into contact with the side surface of the guide arm 83 to prevent the lid 56 from rotating under its own weight.

The operator cleans or replaces the nozzle or the sealing member 46 provided on the first surface 561 of the lid 56 in a state in which the lid 56 is stopped at the maintenance position. At this time, since the first surface 561 on which the nozzle or the sealing member 46 is provided faces upward, the nozzle or the sealing member 46 may be easily cleaned or replaced.

Thereafter, the operator returns the lid 56 from the maintenance position to the closed position by reversing the procedure, and fits the lock key 64 into the pair of upper and lower fitting holes 65.

Although not shown, the support member 80 may include a linear motion guide. The linear motion guide guides the lid 56 toward and away from the opening 55 of the pressure container 52 (e.g., in the Y-axis positive direction and the Y-axis negative direction). Further, the support member 80 may include rolling elements that roll as the lid 56 moves.

As shown in FIGS. 3A and 3B, the drying unit 34 may include a position sensor 89 configured to detect that the lock key 64 is located at the locked position. The locked position is a position at which the lock key 64 presses the lid 56 from the side opposite to the opening 55 of the pressure container 52. Further, the locked position is a position at which the lock key 64 is fitted into both of the pair of upper and lower fitting holes 65. The position sensor 89 is provided for each lock key 64. Before the supply mechanism 57 pressurizes the inside of the pressure container 52, the control device 9 uses the position sensor 89 to confirm that all the lock keys 64 are located at the locked position.

Similarly, the drying unit 34 may include a position sensor 49 configured to detect that the lock key 62 is located at the locked position. The locked position is a position at which the lock key 62 presses the lid 54 from the side opposite to the opening 53 of the pressure container 52. Further, the locked position is a position at which the lock key 62 is fitted into both of the pair of upper and lower fitting holes 63. The position sensor 49 is provided for each lock key 62. Before the supply mechanism 57 pressurizes the inside of the pressure container 52, the control device 9 uses the position sensor 49 to confirm that all the lock keys 62 are located at the locked position.

Further, as shown in FIGS. 4A and 4B, the drying unit 34 may include a position sensor 48 configured to detect that the lid 54 is located at the closed position. The closed position is a position at which the lid 54 closes the opening 53 of the pressure container 52. Before the supply mechanism 57 pressurizes the inside of the pressure container 52, the control device 9 uses the position sensor 48 to confirm that the lid 54 is located at the closed position.

Next, referring mainly to FIG. 1 again, an example of parts used in a pre-treatment and a post-treatment of maintenance of the drying unit 34 will be described. The drying unit 34 includes panels 71 and 72 and electromagnetic locks 73 and 74. The panels 71 and 72 separate the internal space and the external space of the drying unit 34. The pressure container 52, the lids 54 and 56, the supply mechanism 57, the discharge mechanism 47, and the like are provided in the internal space of the drying unit 34. The panel 71 is provided on the side surface of the drying unit 34 facing the maintenance region 35. The panel 72 is provided on the side surface of the drying unit 34 opposite to the first transfer region 31.

Under the control of the control device 9, the electromagnetic lock 73 may be switched between a locked state in which the panel 71 is fixed at a position that restricts access from the external space to the internal space of the drying unit 34, and an unlocked state in which the panel 71 is allowed to move. Similarly, under the control of the control device 9, the electromagnetic lock 74 may be switched between a locked state in which the panel 72 is fixed at a position that restricts access from the external space to the internal space of the drying unit 34, and an unlocked state in which the panel 72 is allowed to move. The electromagnetic locks 73 and 74 are provided inside the panels 71 and 72 so that they cannot be operated by the operator.

The drying unit 34 includes a switch 93. The switch 93 is provided on the outside of the panels 71 and 72 so that it may be operated by the operator. The switch 93 simultaneously switches the state of the first driver (for example, the linear motion mechanism 60 and the rotation mechanism 61) and the state of the second driver (for example, the elevating mechanism 66) between a state in which the first driver and the second driver are electrically connected to a power supply (not shown) and a state in which the first driver and the second driver are electrically disconnected from the power supply (not shown). By operating the switch 93, automatic movement of the lid 54 and the lock key 62 may be prohibited.

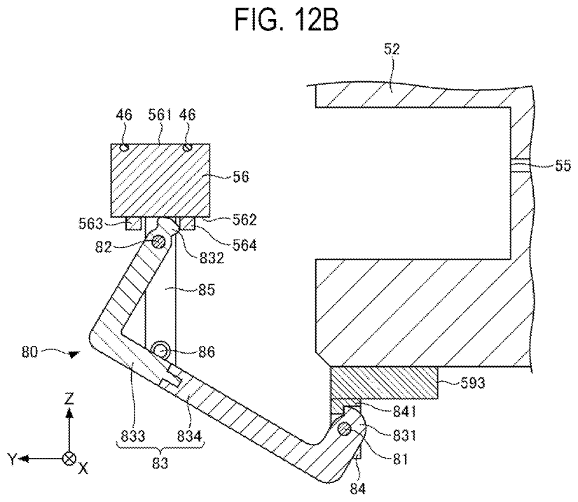

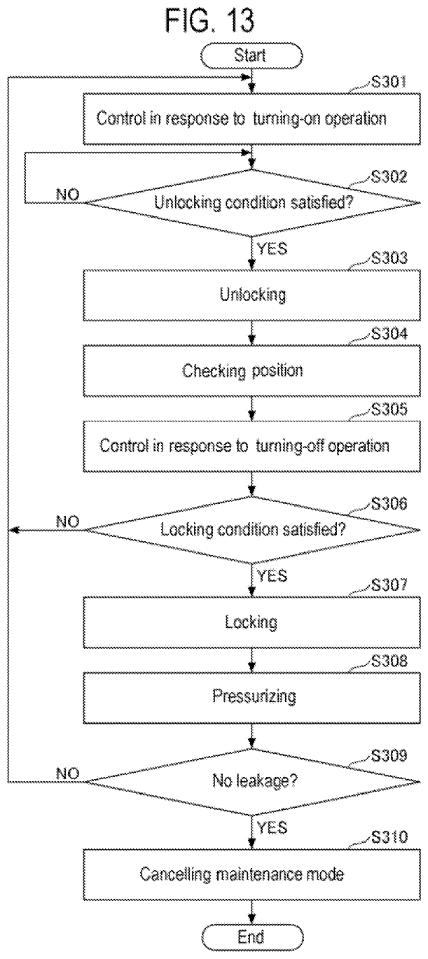

Next, an example of a maintenance method for the drying unit 34 will be described mainly with reference to FIG. 13. The process shown in FIG. 13 is performed under the control of the control device 9. The process shown in FIG. 13 is started when the control device 9 implements a maintenance mode in which the transfer of the substrate W to the drying unit 34 is prohibited and when the operator turns on the switch 93.

First, the control device 9 executes control in response to the turning-on operation of the switch 93 (step S301). The control in response to the turning-on operation of the switch 93 includes, for example, control for electrically disconnecting the first driver and the second driver from the power supply. The lid 54 is stopped at the standby position, and the lock key 62 is stopped at the unlocked position. The lid 56 is located at the closed position, and the lock key 64 is located at the locked position.

Further, the control in response to the turning-on operation of the switch 93 includes control for electrically disconnecting heating mechanism HE11 and line heaters LH11 and LH12 from the power supply. The temperature of the fluid in the supply flow path L11, the pressure container 52, and the discharge flow path L12 decreases. The operator does not need to wear a heat-resistant cloth, which may improve work efficiency. The control device 9 monitors the temperature of the fluid using temperature sensors T11, T12 and T13.

Further, the control in response to the turning-on operation of the switch 93 includes control for reducing the pressure of the fluid in the supply flow path L11, the pressure container 52, and the discharge flow path L12 by operating the on-off valves V11, V12, V13, etc. The pressure of the fluid returns to the atmospheric pressure. There is no risk of the fluid being injected during a maintenance work, which improves the workability. The control device 9 monitors the pressure of the fluid using pressure sensors P11, P12 and P13.

Subsequently, the control device 9 checks whether an unlocking condition is satisfied (step S302). The unlocking condition is a condition under which the control device 9 switches the state of the electromagnetic locks 73 and 74 from the locked state to the unlocked state. The control device 9 maintains the electromagnetic locks 73 and 74 in the locked state and prohibits the operator from entering the internal space of the drying unit 34 until the unlocking condition is satisfied. When the unlocking condition is satisfied (YES in step S302), the control device 9 switches the state of the electromagnetic locks 73 and 74 from the locked state to the unlocked state (step S303). Details of the unlocking condition will be described later.

The unlocking conditions include, for example, (A1) that the detection values of the pressure sensors P11, P12 and P13 are below a threshold value, and (A2) that the detection values of the concentration sensors D11 and D12 are below a threshold value. The threshold value of the pressure is, for example, substantially equal to the atmospheric pressure. The threshold value of the concentration is, for example, substantially equal to the CO₂ concentration in the atmosphere. The operator may be prohibited from entering the internal space of the drying unit 34 until the pressure of the fluid becomes less than the threshold value and the concentration of the fluid (for example, the CO₂ concentration) becomes less than the threshold value. The operator does not need to wear an oxygen mask or the like when entering the internal space of the drying unit 34.

In addition to (A1) and (A2) above, the unlocking condition may include (A3) that the detection values of the temperature sensors T11 and T12 are below a threshold value. The threshold value of the temperature is set to allow the operator to work normally in the internal space of the drying unit 34. The operator may be prohibited from entering the internal space of the drying unit 34 until the temperature of the fluid falls below the threshold value. The heat capacity of the pressure container 52 is large, and the pressure container 52 is difficult to cool down. Therefore, the unlocking condition does not need to include (A4) that the detection value of the temperature sensor T13 is less than or equal to the threshold value. However, the unlocking condition may include (A4) instead of or in addition to (A3).

As mentioned above, the heat capacity of the pressure container 52 is large, and the pressure container 52 is difficult to cool down. Therefore, the drying unit 34 may include a cooler (not shown) that cools the pressure container 52. The cooler causes a refrigerant to flow through the flow path of the pressure container 52, for example. The refrigerant may be a liquid such as water or a gas such as an air.

The unlocking condition may include not only (A1) and (A2) but also (A5) that the first driver (for example, the linear motion mechanism 60 and the rotation mechanism 61) is electrically disconnected from the power supply. The operator may be prohibited from entering the internal space of the drying unit 34 until the automatic movement of the lid 54 is prohibited. (A5) is satisfied when the operator turns on the switch 93. (A5) may be used in combination with (A3) or (A4). The unlocking condition may include at least one of (A3) to (A5) in addition to (A1) and (A2).

The unlocking condition may include not only (A1) and (A2), but also (A6) that the second driver (for example, the elevating mechanism 66) is electrically disconnected from the power supply. The operator may be prohibited from entering the internal space of the drying unit 34 until automatic movement of the lock key 62 is prohibited. (A6) is satisfied when the operator turns on the switch 93. (A6) may be used in combination with (A3), (A4) or (A5). The unlocking condition may include at least one of (A3) to (A6) in addition to (A1) and (A2).

The unlocking conditions may include not only (A1) and (A2) but also (A7) that a maintenance mode is in progress. The operator may be prohibited from entering the internal space of the drying unit 34 until the transfer of the substrate W to the drying unit 34 is prohibited. (A7) may be used in combination with (A3), (A4), (A5) or (A6). The unlocking condition may include at least one of (A3) to (A7) in addition to (A1) and (A2).

The unlocking conditions may include not only (A1) and (A2) but also (A8) that the supply mechanism 57 has stopped supplying a fluid to the pressure container 52. It is possible to prevent (A1) and (A2) from being not satisfied again after they have been satisfied once. (A8) is satisfied when the operator turns on the switch 93. (A8) may be used in combination with (A3), (A4), (A5), (A6) or (A7). The unlocking condition may include at least one of (A3) to (A8) in addition to (A1) and (A2).

After the control device 9 switches the state of the electromagnetic locks 73 and 74 from the locked state to the unlocked state (after step S303), the operator moves the panels 71 and 72 and enters the internal space of the drying unit 34 to perform maintenance on the drying unit 34. For example, the operator removes the lid 54, then cleans or replaces the sealing member 44 attached to the lid 54, and then attaches the lid 54. Alternatively, the operator may remove the lid 56 and lock key 64, may then clean or replace the nozzle or the sealing member 46 attached to the lid 56, and may than attach the lid 56 and lock key 64. The maintenance of the drying unit 34 that does not involve removing and attaching the lids 54 and 56 and the lock keys 62 and 64 may be performed.

After step S303, the control device 9 uses the position sensors 48, 49, 75, 78, etc. to check whether the lids 54 and 56 and the lock keys 62 and 64 are all located at desired positions (step S304). It is possible to check whether at least one of the lids 54 and 56 and the lock keys 62 and 64 has been removed. When a component is removed, the control device 9 may control an alarm output device (not shown) to issue an alarm until the removed component is attached. The alarm output device includes, for example, at least one of a display device, a buzzer, and a warning light. By issuing the alarm, it is possible to call the attention of the operator.

After finishing the maintenance of the drying unit 34, the operator confirms that no alarm has been issued, and turns off the switch 93. Thereafter, the control device 9 performs control in response to the turning-off operation of the switch 93 (step S305). The control in response to the turning-off operation of the switch 93 includes, for example, control for electrically connecting the first driver and the second driver to the power supply. The lid 54 is moved from the standby position to the closed position, and the lock key 62 is moved from the unlocked position to the locked position. The lid 56 is located at the closed position, and the lock key 64 is located at the locked position.

Further, the control in response to the turning-off operation of the switch 93 includes control for electrically connecting the heating mechanism HE11 and the line heaters LH11 and LH12 to the power supply. The temperature of the fluid in the supply flow path L11, the pressure container 52, and the discharge flow path L12 rises to a preset temperature. The control device 9 monitors the temperature of the fluid using the temperature sensors T11, T12 and T13.

Subsequently, the control device 9 checks whether the locking condition is satisfied (step S306). The locking condition is a condition under which the control device 9 switches the state of the electromagnetic locks 73 and 74 from the unlocked state to the locked state. The control device 9 maintains the electromagnetic locks 73 and 74 in the unlocked state until the locking condition is satisfied. When the locking condition is satisfied (YES in step S306), the control device 9 switches the state of the electromagnetic locks 73 and 74 from the unlocked state to the locked state (step S307). Details of the locking condition will be described later.

The locking condition includes, for example, (B1) that the detection values of the temperature sensors T11, T12 and T13 are equal to the preset temperature. When the temperature of the fluid does not reach the preset temperature, some kind of malfunction occurs due to maintenance. When the locking condition is not satisfied (step S307), the control device 9 returns to step S301 and performs the process of step S301 and subsequent steps.

The locking condition may include (B2) that the lids 54 and 56 are located at the closed position, and (B3) that the lock keys 62 and 64 are located at the locked position. It is possible to prevent the panels 71 and 72 from being closed while the lids 54 and 56 and the lock keys 62 and 64 are left unattached. (B2) and (B3) may be used as a pressurization condition described below. The pressurization condition is a condition under which the supply mechanism 57 resumes supplying a fluid to the pressure container 52. The control device 9 prohibits the supply mechanism 57 from supplying a fluid into the pressure container 52 until the pressurization condition is satisfied.

After step S307, the control device 9 controls the supply mechanism 57 to restart the supply of the fluid to the pressure container 52 and executes control to pressurize the inside of the pressure container 52 (step S308). The pressurization condition include (C1) that the control device 9 has already switched the state of the electromagnetic locks 73 and 74 from the unlocked state to the locked state. Since the fluid may leak from the inside of the pressure container 52 to the outside of the pressure container 52 due to incorrect attachment of the sealing members 44, 46, etc., the operator is prohibited from entering the internal space of the drying unit 34 before step S308.

The control device 9 uses leak sensors (for example, concentration sensors D11 and D12) to check whether there is any leakage of a fluid from the sealing members 44 and 46 (step S309). If there is a leakage (NO in step S309), the control device 9 may return to step S301 to perform the process of step S301 and subsequent steps, or may control the alarm output device to issue an alarm. On the other hand, if there is no leakage (YES in step S309), the control device 9 cancels the maintenance mode (step S310). This allows the substrate W to be transferred to the drying unit 34.

Thereafter, although not shown, the control device 9 performs steps S201 to S205 (drying the substrate W) shown in FIG. 6, for example. A dummy substrate may be used instead of the substrate W. While drying the substrate W, the control device 9 acquires a pressure profile using the pressure sensors P11, P12 and P13. Further, while drying the substrate W, the control device 9 acquires a temperature profile using the temperature sensors T11, T12 and T13.

The control device 9 checks whether the pressure profile or the temperature profile acquired after the maintenance falls within a permissible range. If the pressure profile or the temperature profile acquired after the maintenance falls within the permissible range, the control device 9 determines that the maintenance has been appropriately performed, and allows the subsequent process of the substrate W. If the pressure profile or the temperature profile acquired after the maintenance is out of the permissible range, the control device 9 may perform the process of step S301 and subsequent steps shown in FIG. 13 again, or may control the alarm output device to issue an alarm.

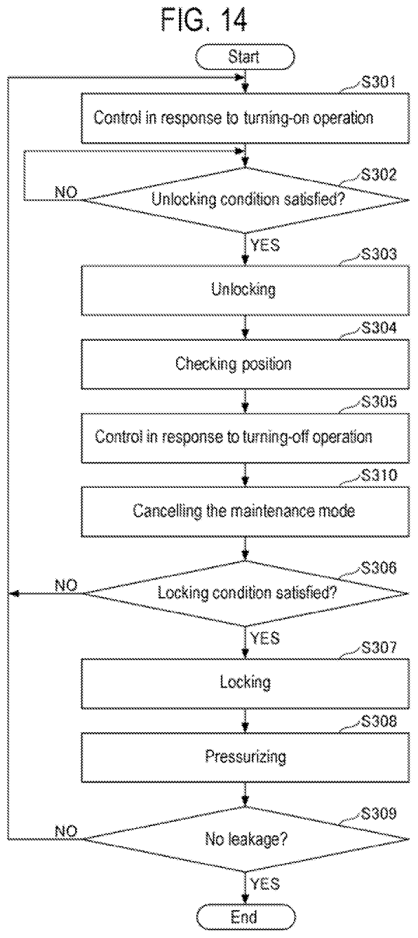

The order of steps S301 to S310 is not limited to the order shown in FIG. 13. For example, as shown in FIG. 14, canceling the maintenance mode (step S310) may be performed before steps S307, S308, or S309. Steps S307, S308, or S309 may be performed in a state in which the substrate W or the dummy substrate is accommodated inside the pressure container 52.

According to the present disclosure in some embodiments, it is possible to smoothly perform maintenance of a drying unit.

Although the embodiments of the substrate processing apparatus and the substrate processing apparatus maintenance method according to the present disclosure have been described above, the present disclosure is not limited to the above embodiments. Various changes, modifications, substitutions, additions, deletions, and combinations may be made within the scope recited in the claims. These fall within the technical scope of the present disclosure.

What is claimed is:

1. A substrate processing apparatus, comprising:
a drying unit configured to replace a liquid film formed on an upper surface of a substrate in a horizontal state with a supercritical fluid and dry the substrate; and
a control device to control the operation of the substrate processing apparatus,
wherein the drying unit further comprises:
a pressure container including a drying chamber provided therein to dry the substrate;
a supply mechanism configured to supply a fluid to the pressure container;
a discharge mechanism configured to discharge the fluid from the pressure container;
a panel configured to separate an internal space in which the pressure container, the supply mechanism and the discharge mechanism are arranged, from an external space;
an electromagnetic lock configured to be switched between a locked state in which the panel is fixed at a position that restricts access from the external space to the internal space and an unlocked state in which the panel is allowed to move; a pressure sensor configured to detect a pressure of the fluid; and a concentration sensor configured to detect a concentration of the fluid; and
wherein an unlocking condition for the control device to switch a state of the electromagnetic lock from the locked state to the unlocked state includes a condition that a detection value of the pressure sensor is less than or equal to a first threshold value and a condition that a detection value of the concentration sensor is less than or equal to a second threshold value.

2. The substrate processing apparatus of claim 1, wherein the drying unit includes a temperature sensor configured to detect a temperature of the fluid, and
wherein the unlocking condition includes a condition that a detection value of the temperature sensor is less than or equal to a third threshold value.

3. The substrate processing apparatus of claim 1, wherein the drying unit includes a lid configured to close an opening of the pressure container and a first driver configured to move the lid, and
wherein the unlocking condition includes a condition that the first driver is electrically disconnected from a power supply.

4. The substrate processing apparatus of claim 3, wherein the drying unit includes a lock key configured to press the lid from a side opposite to the opening and a second driver configured to move the lock key, and
wherein the unlocking condition includes a condition that the second driver is electrically disconnected from the power supply.

5. The substrate processing apparatus of claim 4, further comprising:
a switch configured to simultaneously switch a state of the first driver and a state of the second driver between a state in which the first driver and the second driver are electrically connected to the power supply and a state in which the first driver and the second driver are electrically disconnected from the power supply.

6. The substrate processing apparatus of claim 1, further comprising:
a transfer region adjacent to the drying unit; and
a transfer device configured to transfer the substrate in the transfer region,
wherein the unlocking condition includes a condition that a maintenance mode for prohibiting the transfer of the substrate to the drying unit is in progress.

7. The substrate processing apparatus of claim 1, wherein the unlocking condition includes a condition that the supply mechanism has stopped the supplying the fluid to the pressure container.

8. The substrate processing apparatus of claim 7, wherein a pressurization condition for the supply mechanism to resume the supplying the fluid to the pressure container includes a condition that the control device has already switched the state of the electromagnetic lock from the unlocked state to the locked state.

9. The substrate processing apparatus of claim 8, wherein the drying unit includes a lid configured to close an opening of the pressure container and a first position sensor configured to detect that the lid is located at a closed position at which the lid closes the opening, and
wherein a locking condition in which the control device switches the state of the electromagnetic lock from the unlocked state to the locked state includes a condition that the lid is located at the closed position.

10. The substrate processing apparatus of claim 8, wherein the drying unit includes a lid configured to close an opening of the pressure container, a lock key configured to press the lid from a side opposite to the opening, and a second position sensor configured to detect that the lock key is located at a locked position in which the lock key presses the lid from the side opposite to the opening, and
wherein a locking condition in which the control device switches the state of the electromagnetic lock from the unlocked state to the locked state includes a condition that the lock key is located at the locked position.

11. The substrate processing apparatus of claim 1, wherein the drying unit includes a lid configured to close an opening of the pressure container, a sealing member configured to seal a gap between the pressure container and the lid, and a leak sensor configured to detect a leakage of the fluid from the sealing member.

12. A substrate processing apparatus maintenance method for a substrate processing apparatus including a drying unit configured to replace a liquid film formed on an upper surface of a substrate in a horizontal state with a supercritical fluid and dry the substrate, and a control device,
wherein the drying unit includes: a pressure container configured to form a drying chamber therein for drying the substrate; a supply mechanism configured to supply a fluid to the pressure container; a discharge mechanism configured to discharge the fluid from the pressure container; a panel configured to separate an internal space in which the pressure container, the supply mechanism and the discharge mechanism are arranged from an external space; an electromagnetic lock configured to be switched between a locked state in which the panel is fixed at a position that restricts access from the external space to the internal space and an unlocked state in which the panel is allowed to move; a pressure sensor configured to detect a pressure of the fluid; and a concentration sensor configured to detect a concentration of the fluid,
the substrate processing apparatus maintenance method comprises:
causing the control device to switch a state of the electromagnetic lock from the locked state to the unlocked state, and
wherein an unlocking condition for the control device to switch the state of the electromagnetic lock from the locked state to the unlocked state includes a condition that a detection value of the pressure sensor is less than or equal to a first threshold value and a condition that a detection value of the concentration sensor is less than or equal to a second threshold value.

13. The substrate processing apparatus maintenance method of claim 12, wherein the drying unit includes a temperature sensor configured to detect a temperature of the fluid, and
wherein the unlocking condition includes a condition that a detection value of the temperature sensor is less than or equal to a third threshold value.

14. The substrate processing apparatus maintenance method of claim 12, wherein the drying unit includes a lid configured to close an opening of the pressure container and a first driver configured to move the lid, and
wherein the unlocking condition includes a condition that the first driver is electrically disconnected from a power supply.

15. The substrate processing apparatus maintenance method of claim 14, wherein the drying unit includes a lock key configured to press the lid from a side opposite to the opening and a second driver configured to move the lock key, and
wherein the unlocking condition includes a condition that the second driver is electrically disconnected from the power supply.

16. The substrate processing apparatus maintenance method of claim 12, wherein the substrate processing apparatus further includes a transfer region adjacent to the drying unit and a transfer device configured to transfer the substrate in the transfer region, and
wherein the unlocking condition includes a condition that a maintenance mode for prohibiting the transfer of the substrate to the drying unit is in progress.

17. The substrate processing apparatus maintenance method of claim 12, wherein the unlocking condition includes a condition that the supply mechanism has stopped the supplying the fluid to the pressure container.

18. The substrate processing apparatus maintenance method of claim 17, further comprising:
causing the supply mechanism to resume the supplying the fluid to the pressure container,
wherein a pressurization condition for the supply mechanism to resume the supplying the fluid to the pressure container include a condition that the control device has already switched the state of the electromagnetic lock from the unlocked state to the locked state.

19. The substrate processing apparatus maintenance method of claim 18, wherein the drying unit includes a lid configured to close an opening of the pressure container and a first position sensor configured to detect that the lid is located at a closed position at which the lid closes the opening,
wherein the substrate processing apparatus maintenance method comprises causing the control device to switch the state of the electromagnetic lock from the unlocked state to the locked state, and
wherein a locking condition for the control device to switch the state of the electromagnetic lock from the unlocked state to the locked state includes a condition that the lid is located at the closed position.

20. The substrate processing apparatus maintenance method of claim 18, wherein the drying unit includes a lid configured to close an opening of the pressure container, a lock key configured to press the lid from a side opposite to the opening, and a second position sensor configured to detect that the lock key is located at a locked position in which the lock key presses the lid from the side opposite to the opening,
wherein the substrate processing apparatus maintenance method comprises causing the control device to switch the state of the electromagnetic lock from the unlocked state to the locked state, and
wherein a locking condition for the control device to switch the state of the electromagnetic lock from the unlocked state to the locked state includes a condition that the lock key is located at the locked position.
